(19) United States
(12) Patent Application Publication
(10) Pub. No.: US 2007/0285081 A1
(43) Pub. Date: Dec. 13, 2007

(54) Method and system for statistical measurement and processing of a repetitive signal

(76) Inventors: James A. Carole, Colorado Springs, CO (US); Michael C. Holloway, Colorado Springs, CO (US); Dennis J. Weller, Colorado Springs, CO (US); Richard Douglas Eads, Colorado Springs, CO (US)

Correspondence Address: AGILENT TECHNOLOGIES INC., INTELLECTUAL PROPERTY ADMINISTRATION,LEGAL DEPT., MS BLDG. E P.O. BOX 7599, LOVELAND, CO, 80537, US

(21) Appl. No.: 11/435,117

(22) Filed: May 16, 2006

(51) Int. Cl. G01R 13/34

(52) U.S. Cl. 324/76.58

(57) ABSTRACT

A method and system acquires a set of samples of a periodic signal at a constant sample rate in a primary memory, calculates a variance between the set of samples and an ideal set of samples to create a variance data set, stores the variance set into a secondary memory, concatenates each variance data set to create a concatenated data set, statistically processes the concatenated data set, and presents the statistically processed data.

### BACKGROUND

Certain statistical timing measurements of periodic electrical signals make it desirable to acquire a large number of unit intervals against which the measurement is made. As used herein, a unit interval in the context of a periodic signal is a full cycle of the periodic signal. For purposes of accuracy and resolution for timing measurements, it is desirable to acquire the data with a high speed real time sampler. For statistical time measurements to be valid, a statistically significant number of unit intervals should be evaluated. At high speed sampling rates, therefore, a relatively large amount of data must be gathered to obtain an appropriate number of unit intervals to provide a desired confidence threshold at a desired accuracy.

It is possible to acquire data for timing measurements using a high speed real time digital oscilloscope. In some cases, there is insufficient memory associated with the real time sampler to capture enough unit intervals in a single acquisition. In order to acquire the desired number of unit intervals, therefore, it is beneficial to acquire the data in a plurality of acquisitions.

As an example, it is desired to measure and characterize jitter of a spread spectrum clock signal. Measurement of a 200 MHz clock signal with 30-33 kHz spread spectrum modulation at a sampling rate of 40 Giga samples/sec, a primary memory depth of 2 Mega samples acquires approximately 6000 unit intervals. A statistically valid timing measurement might require between 128,000 and 1,000,000 unit intervals. Therefore, in the example, it is advantageous to make 22 or more acquisitions to obtain enough unit intervals. Accordingly, there is a need to obtain samples over multiple acquisitions in order to support statistical measurements on the signal of interest.

There is a need, therefore, for an improved method of accurately and reliably collecting data suitable for performing statistical measurements on periodic signals.

### BRIEF DESCRIPTION OF THE DRAWINGS

An understanding of the present teachings can be gained from the following detailed description, taken in conjunction with the accompanying drawings of which like reference numerals in different drawings refer to the same or similar elements.

FIG. 1 shows a graph of an amplitude of a clock signal with spread spectrum modulation plotted versus time typical of data gathered by a digitizing oscilloscope.

FIG. 2 shows a graph of an amplitude of a period of the clock signal of FIG. 1 plotted versus time.

FIG. 3 is a flow chart of an embodiment of a method according to the present teachings.

FIG. 4 is a block diagram of an embodiment of a measurement device according to the present teachings.

FIGS. 5 and 7 show flow charts illustrating alternative embodiments of the trimming step.

FIG. 6 shows a graph of an example signal to be processed according to an embodiment of the present teachings.

FIGS. 8 and 9 illustrate an embodiment of a reordering step according to the present teachings.

FIG. 10 illustrates the phenomenon of hysteresis as it applies to the present teachings.

FIG. 11 is a flow chart of an embodiment according to the present teachings for identifying 0-degree and 180-degree phase boundaries.

### DETAILED DESCRIPTION

In the following detailed description, for purposes of explanation and not limitation, example embodiments disclosing specific details are set forth in order to provide an understanding of the present teachings. However, it will be apparent to one of ordinary skill in the art with benefit of the present disclosure that other embodiments according to the present teachings that depart from the specific details disclosed herein remain within the scope of the appended claims. Moreover, descriptions of well-known apparatus and methods may be omitted so as to not obscure the description of the example embodiments, but are contemplated as within the scope of the present teachings.

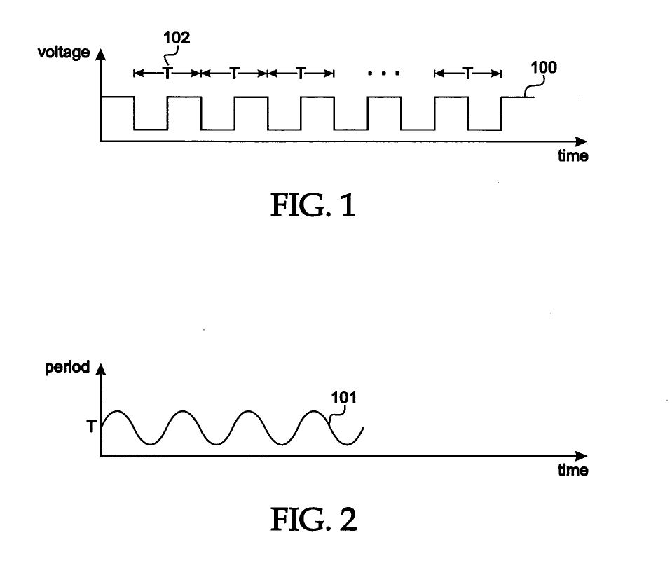

With specific reference to FIG. 1 of the drawings, embodiments of measurements are described with reference to a spread spectrum clock test signal 100 and consistent with those defined in the FB-DIMM High Speed Differential Point To Point Link at 1.5 Volts Specification, Revision 0.85 dated Dec. 15, 2005, the contents of which are hereby incorporated by reference. One of ordinary skill in the art appreciates that the teachings may be applied to other measurements and other types of signals such as those related to a PCI Express™ Card. Some common measurements made for signals related to the PCI Express™ Card are defined in the PCI Express™ Card Electromechanical Specification Revision 1.1 dated Mar. 28, 2005.

FIG. 1 shows an illustration of a portion of a repetitive test signal 100 digitally sampled over time at a constant sample rate, such as 40 Giga samples/sec. A sampling oscilloscope may be used for this purpose. Depending upon the specific sampling rate, the size of a primary memory and a frequency of the test signal, some number of contiguous unit intervals may be stored in a single pass of the primary memory.

The example in FIG. 1 shows the test signal 100 as a square wave clock signal plotted as a voltage measurement versus time. A frequency of the test signal 100 is high when compared to a frequency of a sine wave signal that frequency modulates it. Because of the high frequency content of the test signal 100, it is difficult to discern the low frequency content of the modulation signal from the time base representation.

With specific reference to FIG. 2 of the drawings, there is shown at reference numeral 101 a graph of an amplitude of a period 102 of the test signal 100 plotted versus time. The time base of FIG. 2 of the drawings is significantly larger than the time base of FIG. 1 of the drawings. As can be appreciated by one of ordinary skill in the art, multiple samples in FIG. 1 comprise a digitization of one period 102 of the test signal 100. Therefore, multiple data points from the digitization of the clock signal 100 renders a single data point for use in the graph of FIG. 2. The greater the number of data points used to represent one cycle 102 of the test signal 100, the greater the accuracy of the signal 101 plotted in FIG. 2. Acquisition of the test signal 100 and measurement and plotting the period 102 of the acquired test signal 100 over time yields a sine wave that represents the modulation frequency 101 of the test signal 100.

In a specific embodiment, it is desirable to make statistical measurements based on a difference between the spread spectrum modulated test signal 102 and an unmodulated ideal constant frequency clock. Some refer to the difference between a measured signal period versus the ideal signal period as the time interval error or “TIE”. The TIE is cyclical in nature because of the spread spectrum modulation of the test signal and statistical measurements may be made to indicate behavior of the modulation of the clock.

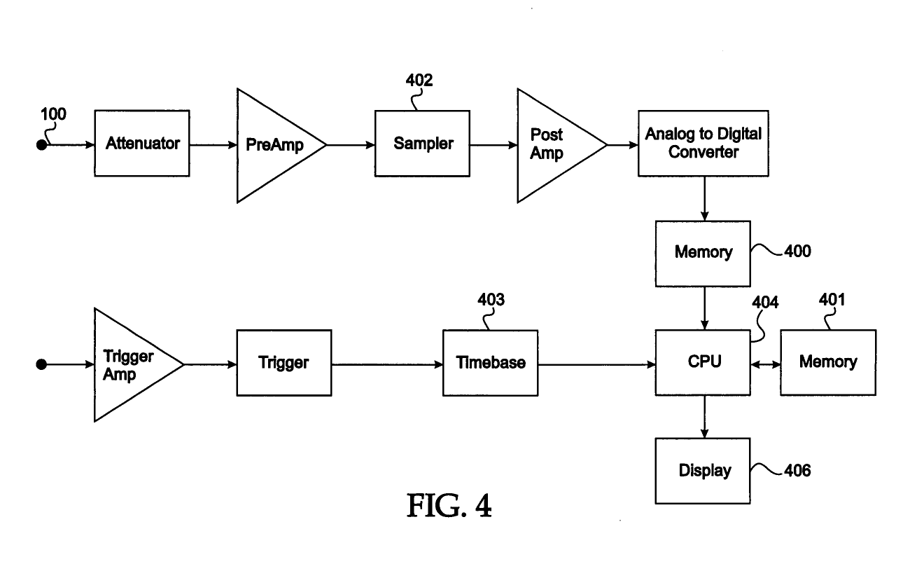

With specific reference to FIG. 4 of the drawings, there is shown a block diagram of a measurement device, such as a sampling oscilloscope, that is appropriate for use in a measurement according to the present teachings. The measurement device comprises a sampler 402 accepting the test signal 100 and operating off a stable high speed time base 403. The test signal 100 is digitized by the sampler 402 and the acquired data is stored in a primary memory 400. A processor 404 transfer the data from the primary memory 400 to the secondary memory 401 and compares it against an ideal signal and processes it. The processed data is then stored in a secondary memory 401. Subsequent acquisitions of the test signal 100 are overwritten in the primary memory 400, processed and the processed data is stored into the secondary memory 401 in contiguous memory locations. Resulting data stored in the secondary memory 401 represents a signal having a longer time duration than a signal able to be stored in the primary memory 400. The processor 404 accepts the signal stored in secondary memory 401, performs statistical processing and then displays results on a display 406. In one embodiment, the processor 404 that processes the captured data prior to storage in the secondary memory 401 is the same as the processor 404 that performs statistical processing on the data and presents the results on a display. One of ordinary skill in the art readily sees, however, that a remote processor or a remote display, or both are also appropriate.

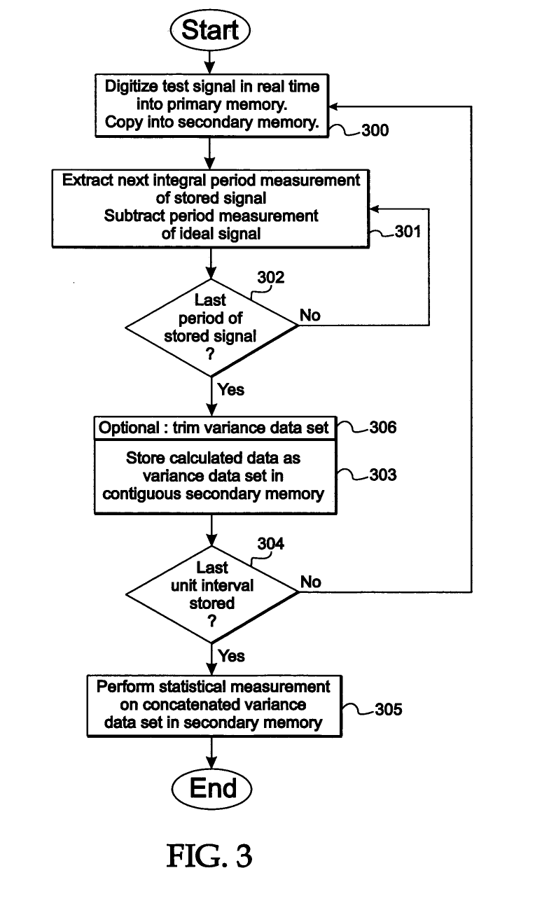

With specific reference to FIG. 3 of the drawings, a method according to the present teachings acquires 300 a set of samples of the test signal 100 at a constant sample rate and stores 300 them in a primary memory 400. The higher the sample rate, the greater the resolution of the timing measurements and the more accurate the TIE measurement. In a specific example, the sample rate is 40 Giga samples/sec and the primary memory 400 is able to store 2 million (2×10⁶) samples. Accordingly, the primary memory 400 holds a sample set representing a portion of the test signal that is 50 usec in length. Each full cycle 102 of the signal 100 captured in the primary memory 400 and transferred to the secondary memory 401 is measured and subtracted 301 from a period of the ideal signal. The process of recovery of the ideal signal and then subtraction of the measured signal from the ideal signal to generate the TIE is disclosed in US Patent Publication 2004/0183518 A1 to Weller et al. published Sep. 23, 2004, the contents of which are hereby incorporated by reference. An embodiment of the teachings in the Weller publication is implemented in Agilent's Infiniium Oscilloscope running Infiniium Software version 5.0. The ideal signal recovery and subtraction process repeats 302 for all integral periods of the signal captured in the primary memory and then transferred to the secondary memory 401. The calculated data points are a variance data set which is stored 303 in a secondary memory 401. After the data in the primary memory 400 is processed, the primary memory 400 is available to store a new set of captured data points from the test signal 100. The capture of the new set of data points from the test signal 100 overwrites the primary memory 400.

The method repeats 304 the step of acquiring a set of samples, calculating 301 the TIE, and storing 303 the resulting variance data set into a next contiguous portion of the secondary memory 401 until a desired number of unit intervals is stored in the secondary memory 401.

Generally, a statistically significant number of unit intervals must be acquired in order to obtain a level of confidence in the statistical measurements. Different measurement applications require a different number of unit intervals and an appropriate number of unit intervals may be determined by one of ordinary skill in the art depending upon the specific measurement desired. The FB-DIMM Specification suggests 1,000,000,000 samples be collected for a specific measurement. The specification, however, does not specifically suggest a number of unit intervals. In a specific measurement, therefore, it is beneficial to determine a number of unit intervals that is appropriate and multiply it by the number of samples collected per unit interval. If the total number of samples collected is above the Nyquist rate and exceeds the suggested 1,000,000,000 samples, then the measurement satisfies both the specification and the general principles of statistical measurements.

In one embodiment according to the present teachings, the contents of the secondary memory 401 are concatenated to represent a single signal having more data points than can be stored in the primary memory 400. Statistical measurements are performed on the concatenated data. Beneficially, a statistical measurement may be made on a data set representing a continuous signal with a statistically significant number of unit intervals even if the primary memory 400 is unable to store as many contiguous unit intervals as are required. Because the unit intervals are collected over time on a periodic signal, there is sufficient representation of the signal that statistical measurements may be made.

Multiple acquisitions often result in phase discontinuities between the separate acquisitions. The phase discontinuities can skew the timing data because it can contain abrupt sample to sample transitions and an inaccurate imbalance of positive and negative energy relative to the actual signal being measured. The characteristics from the phase discontinuities result in measurement errors that can mask the actual error that is of interest.

In another embodiment according to the present teachings, each variance data set is trimmed 306 before storage 303 in the secondary memory 401. In one embodiment, trimming 306 is performed at a predefined phase boundary and the trimmed variance data sets are stored 303 in the secondary memory 401, concatenated and statistically processed 305. In another embodiment, trimming 306 is performed at two predefined phase boundaries and the polarity of integral half cycles is reordered to eliminate discontinuities and properly balance the positive and negative energy of the signal to be processed.

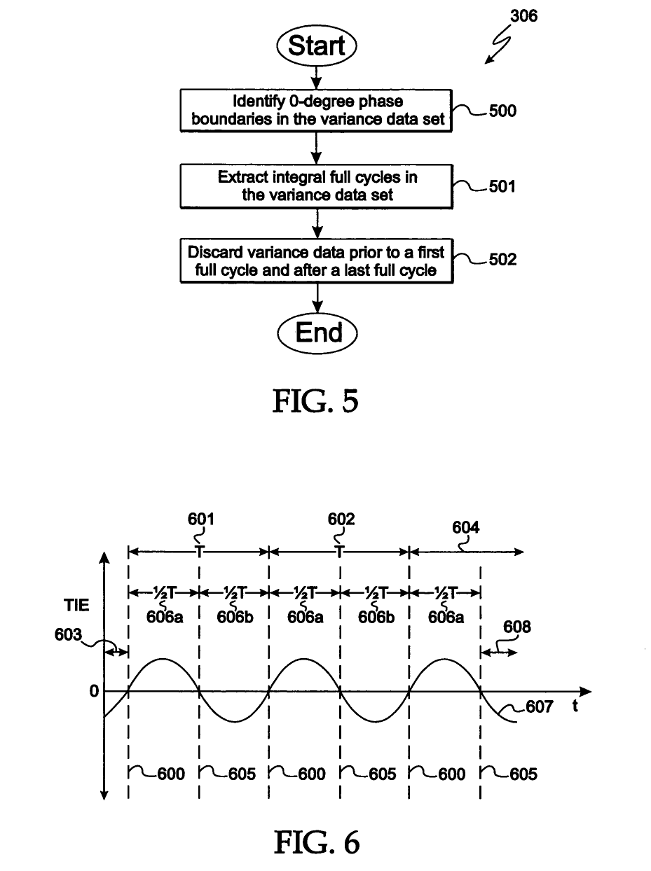

In the specific embodiment of the trimming step 306 that defines a single phase boundary, and with specific reference to FIGS. 5 and 6 of the drawings, negative to positive transitions through zero amplitude are defined as a 0-degree phase boundary 600. All of the 0-degree phase boundaries 600 are identified 500 in the variance data set. Alternatively, any other single phase boundary may be used to delineate integral full cycles in the variance data set. In the present illustration two adjacent 0-degree phase boundaries 600 define a single integral cycle 601 of the variance data set. All integral full cycles in the variance data set are extracted 501. All data prior 603 to a first integral period 601 and all data after 604 a last integral period 602 are discarded 502 and the trimmed variance data set is stored 303 in next contiguous locations of the secondary memory 401. The process repeats 304 for each variance data set until a sufficient number of unit intervals are stored in the secondary memory 401. As one of ordinary skill appreciates, adjacent and contiguous variance data sets naturally have the proper polarity sequence.

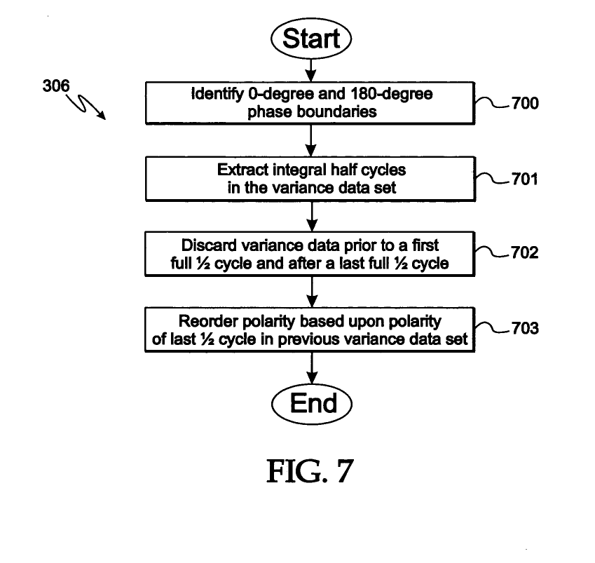

In the other embodiment where trimming 306 is performed at two phase boundaries, less of the variance data set is trimmed allowing more of the variance data set to be used in the statistical measurement. Beneficially, in an embodiment that trims less of each variance data set, fewer primary memory acquisitions must be made in order to collect a sufficient number of unit intervals in the secondary memory 401. With specific reference to FIGS. 6 and 7 of the drawings, 0-degree and 180-degree phase boundaries 600, 605 are identified 700 and integral half cycles 606 of the variance data set are extracted 701. Data in the variance data set prior 603 to the first integral half cycle 606 and after 608 the last integral half cycle is discarded 702.

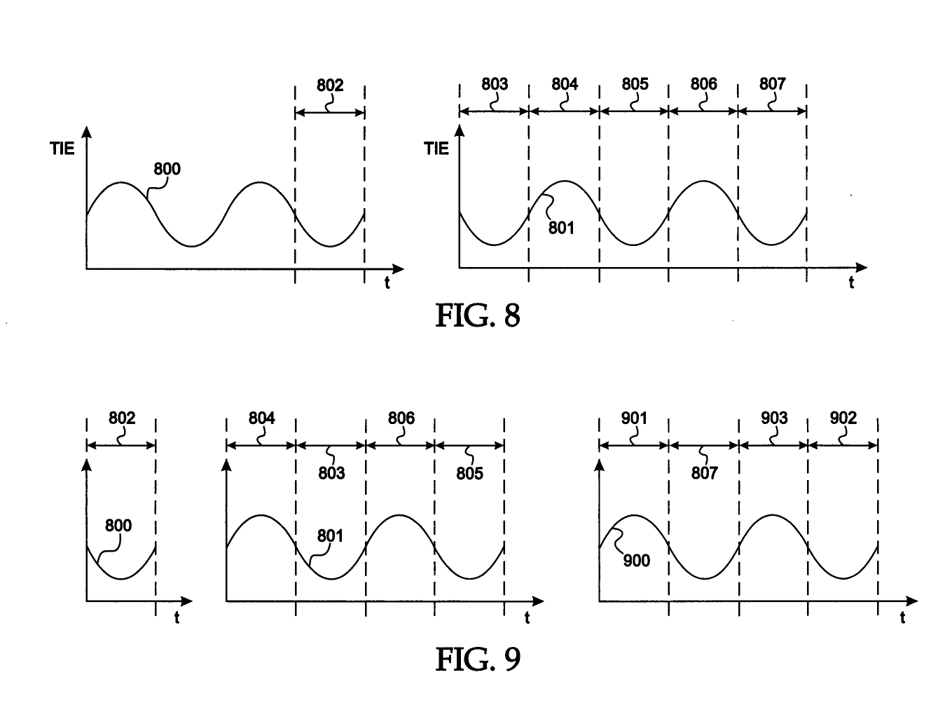

With specific reference to FIG. 8 of the drawings, there is shown a graphical illustration of previous and current variance data sets 800, 801 that have been trimmed to integral half cycle phase boundaries 600, 605. Because delineation is made on integral half cycles boundaries 600, 605, there is a likelihood that at some point in the data collection process as shown in FIG. 8, that a polarity of a last stored integral half cycle 802 in the previous variance data set 800 is the same as a polarity of a first stored integral half cycle 803 in a current variance data set 801. It is desirable to perform statistical measurements on a concatenated variance data set having a balanced energy distribution without abrupt shifts of phase. As one of ordinary skill in the art appreciates, if the variance data is trimmed at integral full cycles 601 as in a previously described embodiment, the issue of polarity consistency does not arise. Accordingly, an embodiment according to the present teachings that trims to integral half cycle boundaries 600, 605 reorders 703 the trimmed current variance data set based upon the polarity of the last stored integral half cycle 802 in the previous variance data set 800.

In a specific embodiment, reordering 703 comprises identifying a polarity of the last stored integral half cycle 802 of the previous variance data set 800. If the polarity of the last stored integral half cycle 802 of the previous variance data set 800 is the same as the polarity of the first integral half cycle 803 of the current variance data set 801, the first integral half cycle 803 of the current variance data set 801 is swapped with a second integral half cycle 804 of the current variance data set 801. All subsequent integral half cycles 805, 806 are also swapped to maintain alternating polarity for the current variance data set 801. Beneficially, polarity of the integral half cycles are swapped, but the majority remain substantially close in time to an actual time of the integral half cycle. If the last integral half cycle 807 in the current variance data set 801 shares the same polarity as the previous integral half cycle after the swap and does not have a partner integral half cycle with which to perform a swap, the next integral half cycle 807 is cached for use in the reordering of a next variance data set 900. In an alternate embodiment, the next integral half cycle 807 that is orphaned in the process of phase correcting is discarded instead of cached for later use.

In specific embodiment that implements reordering 703, there is a positive polarity cache queue and a negative polarity cache queue. Each polarity queue is a first in first out (FIFO) queue that stores integral half cycles 606 having the respective described polarity. As the half cycles 606 are reordered as part of the variance data set processing, the oldest integral half cycle of the required polarity is used first to build the variance data set that is to be stored in the secondary memory 401.

Specifically, and with reference to FIG. 9 of the drawings, in the example given, at the end of the reordering of the current variance data set, there is one integral half cycle 807 in the negative polarity cache queue and no half cycle in the positive polarity cache queue. When processing the next variance data set 900, the cached integral half cycle 807 in the negative polarity cache queue is used as soon as possible in the next variance data set 900. Because there is no data in the positive polarity cache queue, the method pulls the next positive polarity integral half cycle 901 from the next variance data set instead of the FIFO queue.

For example, the system checks the polarity of the last integral half cycle 805 stored in the secondary memory 401. If the polarity cache queue for the desired polarity has data, the system takes the oldest integral half cycle in the queue to build the next variance data set 900. If the polarity cache queue for the desired polarity is empty, the system evaluates the first integral half cycle 901 in the next variance data set 900. If the first integral half cycle in the next variance data set 900 has the desired polarity, it uses it when reordering the next variance data set 900. If the first integral half cycle in the next variance data set 900 has an opposite polarity of the desired polarity, the system looks first to the desired polarity cache queue and if it is empty to the next integral half cycle 903 having the desired polarity. The reordering process 703 continues until all integral half cycles have alternating polarity and an appropriate number of unit intervals are stored in the secondary memory 401.

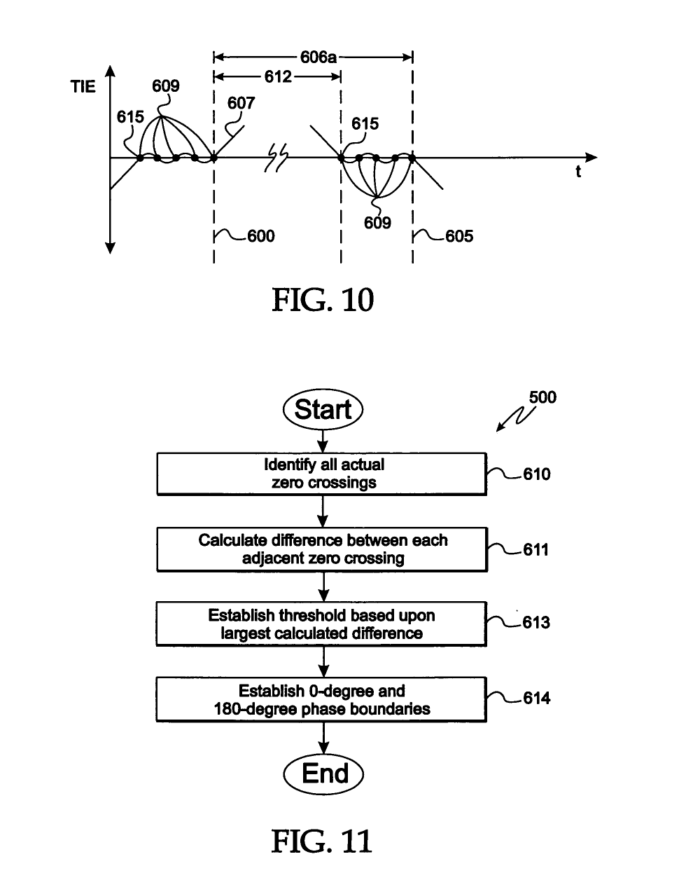

As one of ordinary skill in the art appreciates, some cyclical data, such as TIE data, exhibits hysteresis. The hysteresis may be accommodated as part of the present teachings. In this context and with specific reference to FIG. 10 of the drawings, the term hysteresis refers to the phenomenon wherein the signal to be processed 607 actually crosses zero more than once at each 0-degree phase and 180-degree phase locations in the integral cycle. Only one of the zero crossings, however, properly delineates the integral half cycles 606 of the signal to be processed 607. It is beneficial to measurement accuracy, therefore, to establish a single zero crossing for each 0-degree and 180-degree phase boundary based upon consistent criteria.

In a specific embodiment according to the present teachings and with further reference to FIGS. 10 and 11 of the drawings, there is shown additional details comprising the step of identifying 0-degree and 180-degree phase boundaries 600, 605 in the signal to be processed 607. In the specific embodiment, all actual zero crossings 609 are identified 610. A difference between adjacent actual zero crossings 609 is calculated 611 for each actual zero crossing 609 in the variance data set. A maximum calculated difference 612 in the variance data set between adjacent zero crossings 609 may be reasonably assumed to be close in duration to an integral half cycle 606. A threshold is established 613 based upon the maximum calculated difference 612 between adjacent actual zero crossings 609. In a specific embodiment, the threshold is established as 30% of the maximum calculated difference 612. In a specific embodiment, the threshold is calculated for each variance data set after each acquisition. In an alternate embodiment, the threshold may be calculated once and used as the threshold for subsequent acquisitions until sufficient unit intervals are collected. One of ordinary skill in the art appreciates that other threshold calculations are also appropriate.

Zero(0) degree phase and 180 degree phase boundaries 600, 605 are then established 614 as those actual zero crossings 609 having an post-adjacent zero crossing further than the defined threshold. Those actual zero crossings that do not have a post-adjacent zero crossing further than the defined threshold are not identified as zero crossings, but are used as part of the respective integral half cycle 606 delineated by zero crossings that do meet the threshold requirement of the phase boundary zero crossing. Beneficially, the portion of the signal that exhibits hysteresis, i.e. that portion of the signal containing actual zero crossings 609 that are not phase boundaries, is still used for purposes of building the concatenated data set, but is not used for purposes of defining the phase boundaries 600, 605 of the integral half cycles. As one of ordinary skill in the art appreciates, definition of phase boundaries 600, 605 as described produce consistent use of the actual zero crossings 609 that follow hysteresis 600, 605. As one of ordinary skill in the art further appreciates, consistent use of the zero crossings 609 that precede the hysteresis 615 to define the phase boundaries 600, 605 is equally valid.

The 0-degree phase boundaries 600 are further established as the phase boundaries that precede a positive polarity integral half cycle 606a and the 180-degree phase boundaries 605 are established as the phase boundaries that precede a negative polarity integral half cycle 606b. When the 0-degree and 180-degree phase boundaries 600, 605 are established, the information is used as appropriate in the different embodiments according to the present teachings as illustrated by example in FIGS. 5 and 7.

Embodiments of the teachings are described herein by way of example with reference to the accompanying drawings describing a method and system for capturing and statistically processing a repetitive signal. Other variations, adaptations, and embodiments of the present teachings will occur to those of ordinary skill in the art given benefit of the present teachings.

1. A method comprising:
Acquiring a set of samples of a periodic signal at a constant sample rate in a primary memory,
Calculating a variance between the set of samples and an ideal set of samples to create a variance data set,
Storing the variance set into a secondary memory,
Concatenating a plurality of the acquired variance data sets to create a concatenated data set,
Statistically processing the concatenated data set, and
Presenting the statistically processed data.

2. A method as recited in claim 1 and further comprising trimming the variance data set to at least one phase boundary.

3. A method as recited in claim 2 wherein trimming occurs before storing.

4. A method as recited in claim 2 wherein the step of trimming comprises declaring at least one phase boundary, identifying a first in time phase boundary and a last in time phase boundary, modifying the variance data set by discarding samples in the variance data set occurring prior to the first in time phase boundary and discarding samples in the variance data set occurring after the last in time phase boundary.

5. A method as recited in claim 4 wherein trimming occurs before storing.

6. A method as recited in claim 4 wherein the step of identifying the phase boundaries further comprises
identifying a plurality of zero crossings in the variance data set,
determining a maximum distance between two adjacent zero crossings,
establishing a threshold to be greater than a percentage of the maximum distance,
assigning at least two phase boundaries, wherein the phase boundary is defined as one of the zero crossings having a next adjacent zero crossing further than the threshold.

7. A method as recited in claim 6 wherein the threshold is greater than approximately 30%.

8. A method as recited in claim 4 wherein the variance data between two adjacent phase boundaries is an integral half cycle and further comprising determining a polarity of a last in time integral half cycle of a first variance set and a polarity of each integral half cycle of a second variance set, maintaining the polarities of each integral half cycle in respective positive and negative polarity first in first out (FIFO) queues, and reconstructing the variance data set by alternately storing integral half cycles from one of the polarity queues with an opposite polarity of a last stored integral half cycle.

9. A method as recited in claim 7 wherein determining polarity further comprises basing the polarity on a mid-point each integral half cycle of the variance data set.

10. A system comprising
a sampler operating at a constant sample rate,
a primary memory adapted to store captured samples from the sampler,
a processor adapted to generate a variance data set between the captured samples and an ideal signal, and
a secondary memory adapted to store the variance data set, the processor further adapted to concatenate multiple variance data sets to generate a concatenated data set and statistically measure characteristics of the concatenated data set.

11. A system as recited in claim 10 and a display.

12. A system as recited in claim 10 the processor further adapted to trim the variance data set to at least one phase boundary.

13. A system as recited in claim 12 the processor further adapted to establish a phase boundary criteria, identify a first in time phase boundary and a last in time phase boundary, modify the variance data set by discarding samples in the variance data set occurring prior to the first in time phase boundary and discarding samples in the variance data set occurring after the last in time phase boundary.

14. A system as recited in claim 13 the processor further adapted to identify a plurality of zero crossings in the variance data set, determine a maximum distance between two adjacent zero crossings, establish a threshold to be greater than a percentage of the maximum distance, assign at least two phase boundaries, wherein the phase boundary is defined as one of the zero crossings having a next adjacent zero crossing further than the threshold.

15. A system as recited in claim 14 wherein the threshold is greater than approximately 30%.

16. A system as recited in claim 15 wherein the variance data between two adjacent phase boundaries is an integral half cycle, the processor further configured with instructions to determine a polarity of a last in time integral half cycle of a first variance set and a polarity of each integral half cycle of a second variance set, maintain the polarities of each integral half cycle in respective positive and negative polarity first in first out (FIFO) queues, and reconstruct the variance data set by alternately storage of integral half cycles from one of the polarity queues with an opposite polarity of a last stored integral half cycle.

17. A system as recited in claim 16 wherein the polarity is based on the polarity on a mid-point of each integral half cycle of the variance data set.

18. An apparatus comprising a sampling oscilloscope having a processor and an instruction memory configured with instructions for causing the processor to acquire a set of samples of a periodic signal at a constant sample rate in a primary memory, calculate a variance between the set of samples and an ideal set of samples to create a variance data set, store the variance set into a secondary memory, repeat the acquisition, calculate, and store until the secondary memory contains at least a predetermined plurality of data points, concatenate each variance data set to create a concatenated data set, statistically process the concatenated data set, present the statistically processed data.

19. An apparatus as recited in claim 18 and further comprising a display.

20. An apparatus as recited in claim 18 and further comprising instructions for causing the processor to trim the variance data set to at least one phase boundary.

21. An apparatus as recited in claim 20 and further comprising instructions for causing the processor to establish a phase boundary criteria, identify a first in time phase boundary and a last in time phase boundary, modify the variance data set by discarding samples in the variance data set occurring prior to the first in time phase boundary and discarding samples in the variance data set occurring after the last in time phase boundary.

22. An apparatus as recited in claim 21 and further comprising instructions to identify a plurality of zero crossings in the variance data set, determine a maximum distance between two adjacent zero crossings, establish a threshold to be greater than a percentage of the maximum distance, assign at least two phase boundaries, wherein the phase boundary is defined as one of the zero crossings having a next adjacent zero crossing further than the threshold.

23. An apparatus as recited in claim 22 wherein the threshold is greater than approximately 30%.

24. An apparatus as recited in claim 22 wherein the variance data between two adjacent phase boundaries is an integral half cycle, the instruction memory further configured with instructions for causing the processor to determine a polarity of a last in time integral half cycle of a first variance set and a polarity of each integral half cycle of a second variance set, maintain the polarities of each integral half cycle in respective positive and negative polarity first in first out (FIFO) queues, and reconstruct the variance data set by alternate storage of integral half cycles from one of the polarity queues with an opposite polarity of a last stored integral half cycle.

25. An apparatus as recited in claim 21 wherein the polarity is based on the polarity on a mid-point of each integral half cycle of the variance data set.
